(19) United States
(12) Patent Application Publication
(10) Pub. No.: US 2021/0082854 A1
(43) Pub. Date: Mar. 18, 2021

(54) SEMICONDUCTOR DEVICE AND METHOD FOR MANUFACTURING SEMICONDUCTOR DEVICE

(71) Applicant: KIOXIA CORPORATION, Tokyo (JP)

(72) Inventor: Hiroyuki WAKIOKA, Yokkaichi Mie (JP)

(73) Assignee: KIOXIA CORPORATION, Tokyo (JP)

(21) Appl. No.: 16/937,820

(22) Filed: Jul. 24, 2020

(30) Foreign Application Priority Data
Sep. 18, 2019 (JP) 2019-169873

(51) Int. Cl. H01L 23/00; H01L 23/14; H01L 21/56

(52) U.S. Cl. CPC H01L 24/16; H01L 24/48; H01L 24/05; H01L 2224/16225; H01L 21/563; H01L 24/13; H01L 2224/48228; H01L 23/147

(57) ABSTRACT

A semiconductor device includes a first semiconductor chip including a conductive pad, an insulating layer provided on the conductive pad, and having an aperture exposing a part of the conductive pad, and a first bump layer provided on the insulating layer and connected to the conductive pad via the aperture, and a second semiconductor chip including an electrode and a second bump layer provided on the electrode. The first bump layer includes a recessed portion provided at the aperture and in contact with the second bump layer, and a raised portion provided adjacent the aperture and in contact with the second bump layer.

### CROSS-REFERENCE TO RELATED APPLICATION(S)

This application is based upon and claims the benefit of priority from Japanese Patent Application No. 2019-169873, filed Sep. 18, 2019, the entire contents of which are incorporated herein by reference.

### FIELD

At least one embodiment described herein relates generally to a semiconductor device and a method for manufacturing the semiconductor device.

### BACKGROUND

A semiconductor device such as a three-dimensional memory may be fabricated by performing flip-chip bonding, which joins a first semiconductor chip onto a package substrate or a second semiconductor chip, via bumps, and sealing a space between the first semiconductor chip and the package substrate or the second semiconductor chip with underfill resin.

An example of related art includes JP-A-2011-040471.

### DESCRIPTION OF THE DRAWINGS

FIG. 1 is a sectional schematic diagram used to explain a structural example of a semiconductor chip.

FIG. 2 is a planar schematic diagram used to explain the structural example of the semiconductor chip.

FIG. 3 is a sectional schematic diagram used to explain an example of a method of forming a bump layer.

FIG. 4 is a sectional schematic diagram used to explain the example of the method of forming the bump layer.

FIG. 5 is a sectional schematic diagram used to explain the example of the method of forming the bump layer.

FIG. 6 is a sectional schematic diagram used to explain the example of the method of forming the bump layer.

FIG. 7 is a sectional schematic diagram used to explain the example of the method of forming the bump layer.

FIG. 8 is a sectional schematic diagram used to explain the example of the method of forming the bump layer.

FIG. 9 is a sectional schematic diagram used to explain an example of a method of stacking a plurality of semiconductor chips.

FIG. 10 is a sectional schematic diagram used to explain a second structural example of a semiconductor chip.

FIG. 11 is a planar schematic diagram used to explain the second structural example of the semiconductor chip.

FIG. 12 is a sectional schematic diagram used to explain a third structural example of a semiconductor chip.

FIG. 13 is a planar schematic diagram used to explain the third structural example of the semiconductor chip.

FIG. 14 is a sectional schematic diagram used to explain a fourth structural example of a semiconductor chip.

FIG. 15 is a planar schematic diagram used to explain the fourth structural example of the semiconductor chip.

FIG. 16 is a sectional schematic diagram used to explain a structural example of a semiconductor device.

FIG. 17 is a sectional schematic diagram used to explain another structural example of the semiconductor device.

FIG. 18 is a sectional schematic diagram used to explain a structural example of a memory chip.

### DETAILED DESCRIPTION

At least one embodiment provides preventing or reducing a decrease in reliability of a semiconductor device.

In general, according to at least one embodiment, a semiconductor device includes a first semiconductor chip including a conductive pad, an insulating layer, provided on the conductive pad, and having an aperture exposing a part of the conductive pad, and a first bump layer provided on the insulating layer and connected to the conductive pad via the aperture, and a second semiconductor chip including an electrode and a second bump layer provided on the electrode. The first bump layer includes a recessed portion provided at the aperture and in contact with the second bump layer, and a raised portion provided adjacent the aperture and in contact with the second bump layer.

Hereinafter, embodiments will be described with reference to the drawings. Furthermore, the drawings are schematic ones, and, for example, the relationships between thicknesses and planar dimensions and the ratios in thickness between the respective layers may differ from the actual ones. Moreover, in the embodiments, substantially the same elements are assigned the respective same reference characters, and the description thereof is not repeated.

### First Embodiment

In the present embodiment, a structural example of a stacked body of semiconductor chips (also referred to as a “chip stacked body”) for use in a semiconductor device is described.

### Structural Example of Semiconductor Chip

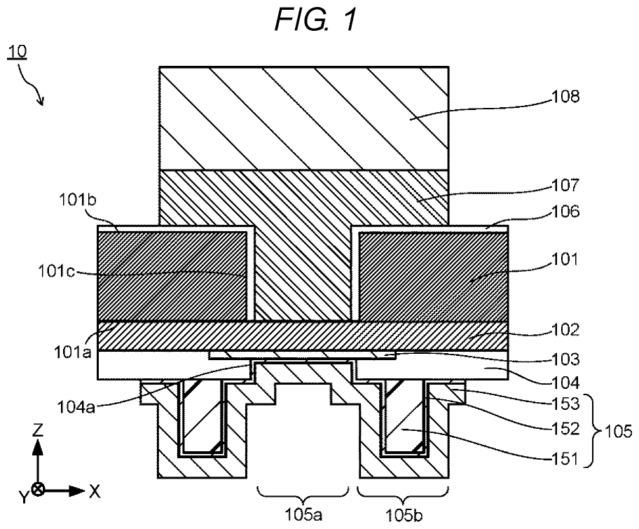

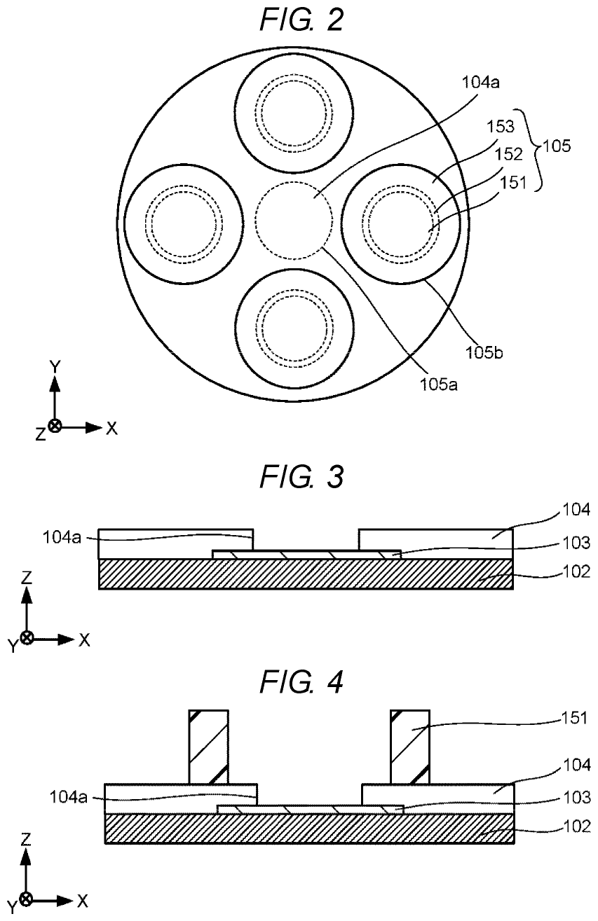

FIG. 1 is a sectional schematic diagram used to explain a structural example of a semiconductor chip for use in a chip stacked body, and illustrates a part of an X-Z cross-section including an X-axis of the semiconductor chip 10 and a Z-axis of the semiconductor chip 10 perpendicular to the X-axis and perpendicular to a Y-axis of the semiconductor chip 10 perpendicular to the X-axis. FIG. 2 is a planar schematic diagram used to explain the structural example of the semiconductor chip, and illustrates a part of an X-Y plane including the X-axis of the semiconductor chip 10 and the Y-axis thereof.

The semiconductor chip 10 includes a substrate 101, an element layer 102, a conductive pad 103, an insulating layer 104, a bump layer 105, an insulating layer 106, an electrode 107, and a bump layer 108.

The substrate 101 includes a surface 101a, a surface 101b located opposite the surface 101a, and a through-hole 101c penetrating through the substrate 101 and extending from the surface 101a to the surface 101b. FIG. 2 is a planar schematic diagram illustrating the semiconductor chip 10 as viewed from the side of the surface 101a. The substrate 101 includes, for example, a wiring substrate. The wiring substrate only needs to have a semiconductor element mountable thereon and to include a wiring network. The wiring substrate may include, for example, a semiconductor substrate such as a silicon substrate, a glass substrate, a resin substrate, or a metallic substrate.

The element layer 102 is provided on the surface 101a. The element layer 102 includes, for example, semiconductor elements such as memory cells.

The conductive pad 103 is provided on the element layer 102. The conductive pad 103 is connected to, for example, semiconductor elements of the element layer 102 via wiring lines. The conductive pad 103 contains, for example, aluminum.

The insulating layer 104 is provided on the element layer 102 and on the conductive pad 103, and has an aperture 104a exposing at least a part of the conductive pad 103. The insulating layer 104 includes, for example, a silicon oxide film or a silicon nitride film.

The bump layer 105 includes a recessed portion 105a provided at the aperture 104a and raised portions 105b provided near the aperture 104a.

The recessed portion 105a is in contact with the conductive pad 103 at the aperture 104a and serves as a connection portion which is connected to the conductive pad 103 via the aperture 104a. Providing the recessed portion 105a at the aperture 104a enables, in the case of forming a chip stacked body by stacking a plurality of semiconductor chips 10, enlarging the contact area between the bump layer 105 of one of the plurality of semiconductor chips 10 and the bump layer 108 of another of the plurality of semiconductor chips 10.

Providing the raised portions 105b near the aperture 104a enables, in the case of forming a chip stacked body by stacking a plurality of semiconductor chips 10, making the connection resistance between the bump layer 105 of one of the plurality of semiconductor chips 10 and the bump layer 108 of another of the plurality of semiconductor chips 10 smaller than that obtained when each raised portion 105b is provided at the aperture 104a.

In the case of forming a chip stacked body by stacking a plurality of semiconductor chips 10, each raised portion 105b serves as a spacer used to control a gap between one of the plurality of semiconductor chips 10 and another of the plurality of semiconductor chips 10. The gap is adjusted according to, for example, the height of each raised portion 105b. While, in FIG. 1 and FIG. 2, a plurality of raised portions 105b is illustrated, the bump layer 105 only needs to include at least one raised portion 105b. When the bump layer 105 includes a plurality of raised portions 105b, the plurality of raised portions 105b may have respective different heights. Moreover, while, in FIG. 1 and FIG. 2, columnar raised portions 105b are illustrated, the shape of each raised portion 105b is not limited to a columnar shape.

The bump layer 105 includes a first layer 151, a second layer 152, and a third layer 153. The stacked structure of the bump layer 105 is not limited to the structure illustrated in FIG. 1 and FIG. 2, and, for example, the third layer 153 does not need to be provided.

The first layer 151 is provided near the aperture 104a. In the case of forming a chip stacked body by stacking a plurality of semiconductor chips 10, it is favorable that the first layer 151 is more unlikely to be deformed than the bump layer 108, and, for example, it is favorable that the first layer 151 is higher in elastic modulus than the bump layer 108.

The first layer 151 contains, for example, a resin material or a metallic material. In the case of forming a chip stacked body by stacking a plurality of semiconductor chips 10, using the metallic material for the first layer 151 enables reducing the electrical resistivity of the raised portion 105b and, therefore, enables reducing the connection resistance between the bump layer 105 of one of the plurality of semiconductor chips 10 and the bump layer 108 of another of the plurality of semiconductor chips 10. The resin material includes, for example, epoxy or acrylic. The metallic material includes, for example, copper (Cu) or nickel (Ni). While, in FIG. 1 and FIG. 2, a columnar first layer 151 is illustrated, the shape of the first layer 151 is not limited to a columnar shape.

The second layer 152 is provided on the first layer 151 and is connected to the conductive pad 103 via the aperture 104a. The second layer 152 includes a single layer or a stack of layers containing at least one metallic element selected from the group including, for example, titanium (Ti) and copper.

The third layer 153 is provided on the second layer 152. The third layer 153 includes a single layer or a stack of layers containing at least one metallic element selected from the group including, for example, nickel and copper. Furthermore, the surface of the third layer 153 may be covered with a layer containing gold (Au). Furthermore, the third layer 153 does not need to be provided.

The insulating layer 106 is provided on the surface 101b and on the inner wall surface of the through-hole 101c. The insulating layer 106 includes, for example, a silicon oxide film.

The electrode 107 is provided on the insulating layer 106, penetrates through the substrate 101, and is connected to semiconductor elements of the element layer 102 via wiring lines at the through-hole 101c. The electrode 107 includes a single layer or a stack of layers containing at least one metallic element selected from the group including, for example, nickel and copper.

The bump layer 108 is provided on the electrode 107. The bump layer 108 includes a solder layer containing, for example, tin.

### Example of Method of Forming Bump Layer 105

FIG. 3 to FIG. 8 are sectional schematic diagrams used to explain an example of a method of forming the bump layer 105, and illustrate a part of an X-Z cross-section of the semiconductor chip 10.

First, as illustrated in FIG. 3, the method forms the conductive pad 103 on the element layer 102, forms the insulating layer 104 on the conductive pad 103, and forms the aperture 104a, which exposes a part of the conductive pad 103, by etching a part of the insulating layer 104.

Next, as illustrated in FIG. 4, the method forms the first layer 151 on the insulating layer 104.

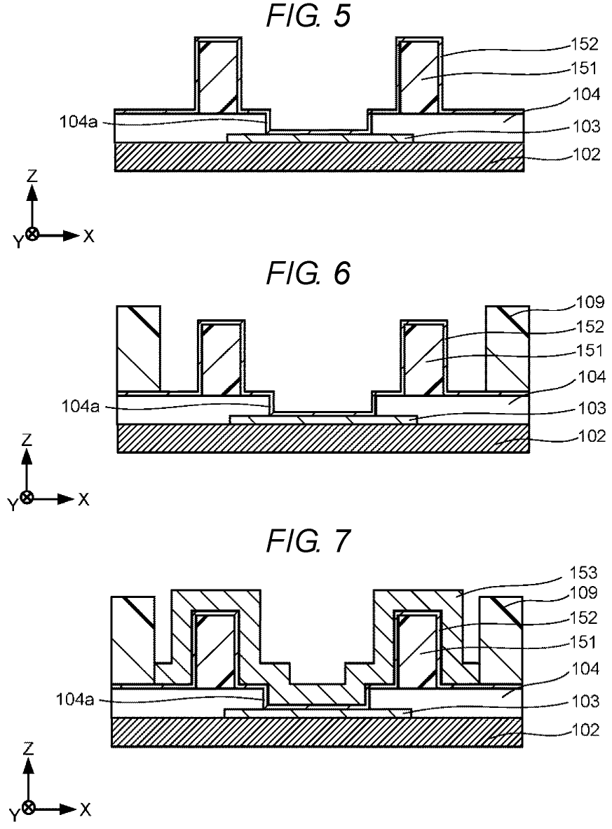

Next, as illustrated in FIG. 5, the method forms the second layer 152 on the conductive pad 103 in the aperture 104a, on the insulating layer 104, and on the first layer 151.

Next, as illustrated in FIG. 6, the method forms a mask layer 109 on the second layer 152. The mask layer 109 is formed with use of, for example, a photolithography technique.

Next, as illustrated in FIG. 7, the method forms the third layer 153 on the second layer 152 with use of the mask layer 109. The third layer 153 is formed with use of, for example, a plating method.

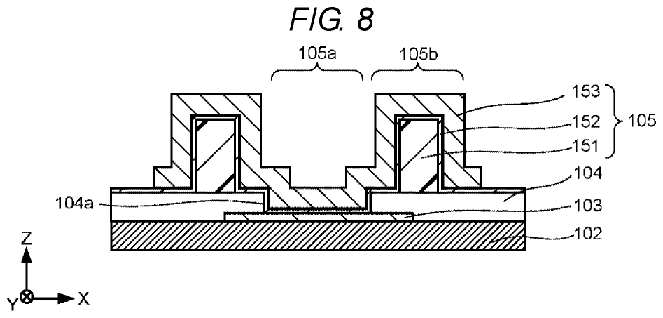

Next, as illustrated in FIG. 8, the method removes the mask layer 109, and etches a part of the second layer 152. The above-described processing enables forming the bump layer 105 including the recessed portion 105a and the raised portions 105b.

### Example of Method of Stacking Plurality of Semiconductor Chips

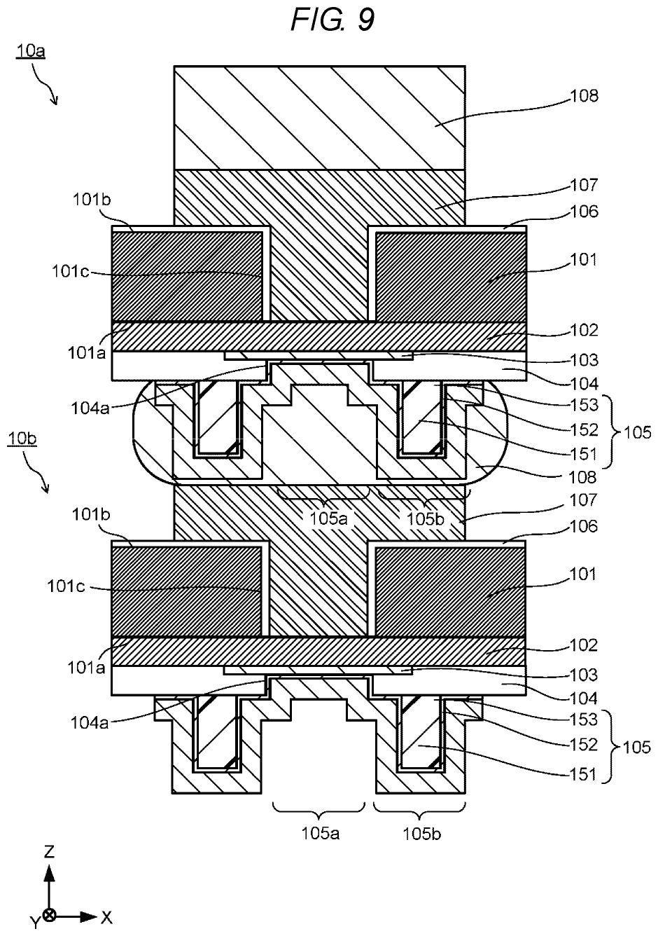

FIG. 9 is a sectional schematic diagram used to explain an example of a method of stacking a plurality of semiconductor chips, and illustrates a part of an X-Z cross-section of a semiconductor chip 10a, which is one of the plurality of semiconductor chips 10, and a part of an X-Z cross-section of a semiconductor chip 10b, which is another of the plurality of semiconductor chips 10.

In the case of stacking the semiconductor chip 10a and the semiconductor chip 10b, as illustrated in FIG. 9, the method brings the bump layer 105 and the bump layer 108 into contact with each other in such a manner that the recessed portion 105a and raised portions 105b of the semiconductor chip 10a are in contact with the bump layer 108 of the semiconductor chip 10b. The recessed portion 105a may be filled with, for example, solder of the bump layer 108. The raised portion 105b may be in contact with the electrode 107. After stacking all of the semiconductor chips 10, the method heats and temporarily fixes the chip stacked body, for example, at a temperature lower than 200° C. and then heats and actually fixes the chip stacked body at a temperature higher than or equal to 200° C., thus being able to join a plurality of semiconductor chips 10.

As described above, according to at least one embodiment, in the case of forming a chip stacked body by stacking a plurality of semiconductor chips 10, providing the recessed portion 105a at the bump layer 105 enables enlarging the contact area between the bump layer 105 of one of the plurality of semiconductor chips 10 and the bump layer 108 of another of the plurality of semiconductor chips 10, and, therefore, enables preventing or reducing an increase of the electrical resistivity. Moreover, according to the present embodiment, in the case of forming a chip stacked body by stacking a plurality of semiconductor chips 10, providing the raised portion 105b at the bump layer 105 enables controlling a gap between one of the plurality of semiconductor chips 10 and another of the plurality of semiconductor chips 10. The joining technique using solder bumps, which is used for chip-on-chip connection and flip-chip connection, has difficulty in controlling a gap, so that short-circuiting of a joining portion caused by excess crush of solder or opening of a joining portion caused by insufficient weight application may occur in some cases. On the other hand, providing the recessed portion 105a and the raised portion 105b enables, while preventing or reducing an increase of the electrical resistivity, readily controlling a gap, preventing or reducing the occurrence of short-circuiting, and stably filling the gap with underfill resin. Additionally, providing the recessed portion 105a and the raised portion 105b enables enlarging the contact area between the bump layer 105 of one of the plurality of semiconductor chips 10 and the bump layer 108 of another of the plurality of semiconductor chips 10, and, therefore, enables preventing or reducing the occurrence of short-circuiting in a joining portion. Therefore, at least one embodiment is able to prevent or reduce a decrease in reliability of a semiconductor device.

### Second Embodiment

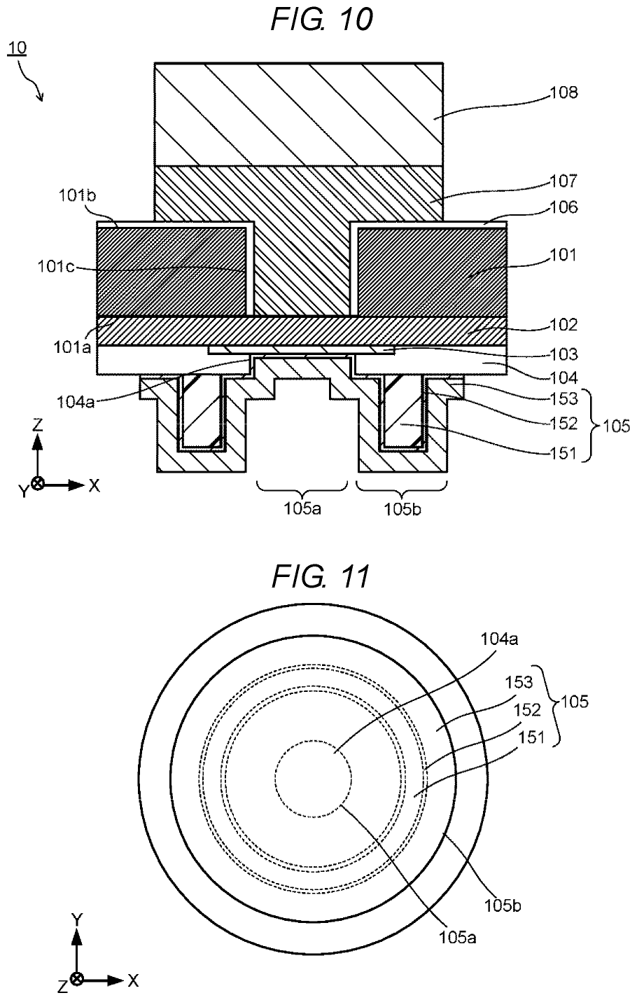

In at least one embodiment, a second structural example of a semiconductor chip for use in a chip stacked body is described. FIG. 10 is a sectional schematic diagram used to explain the second structural example of the semiconductor chip, and illustrates a part of an X-Z cross-section of the semiconductor chip 10. FIG. 11 is a planar schematic diagram used to explain the second structural example of the semiconductor chip, and illustrates a part of an X-Y plane of the semiconductor chip 10. FIG. 11 is a planar schematic diagram of the semiconductor chip 10 as viewed from the side of the surface 101a.

The semiconductor chip 10 includes a substrate 101, an element layer 102, a conductive pad 103, an insulating layer 104, a bump layer 105, an insulating layer 106, an electrode 107, and a bump layer 108. Furthermore, the substrate 101, the element layer 102, the conductive pad 103, the insulating layer 104, the insulating layer 106, the electrode 107, and the bump layer 108 are the same as the substrate 101, the element layer 102, the conductive pad 103, the insulating layer 104, the insulating layer 106, the electrode 107, and the bump layer 108, respectively, in the first embodiment, and, therefore, the description thereof is omitted here.

The bump layer 105 includes a recessed portion 105a provided in an aperture 104a and an annular raised portion 105b surrounding the recessed portion 105a. In the case of forming a chip stacked body by stacking a plurality of semiconductor chips 10, providing the annular raised portion 105b enables preventing or reducing the collapse of the raised portion 105b. Further description of the recessed portion 105a and the raised portion 105b can be replaced by the description of the recessed portion 105a and the raised portion 105b in the first embodiment as appropriate.

The bump layer 105 includes a first layer 151, a second layer 152, and a third layer 153. The first layer 151 surrounds the aperture 104a. The second layer 152 is provided on the first layer 151 and is connected to the conductive pad 103 via the aperture 104a. The third layer 153 is provided on the second layer 152. Further description of the first layer 151, the second layer 152, and the third layer 153 can be replaced by the description of the first layer 151, the second layer 152, and the third layer 153 in the first embodiment as appropriate.

As described above, according to at least one embodiment, in the case of forming a chip stacked body by stacking a plurality of semiconductor chips 10, providing the annular raised portion 105b enables preventing or reducing the collapse of the raised portion 105b. Therefore, since it is possible to prevent or reduce a defective junction, the at least one embodiment is able to prevent or reduce a decrease in reliability of a semiconductor device.

### Third Embodiment

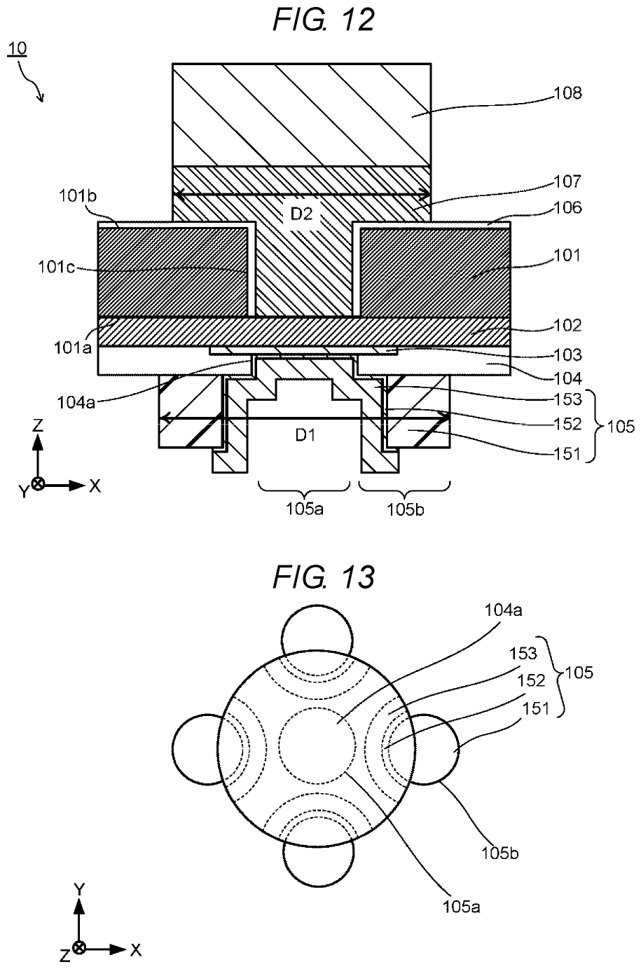

In at least one embodiment, a third structural example of a semiconductor chip for use in a chip stacked body is described. FIG. 12 is a sectional schematic diagram used to explain the third structural example of the semiconductor chip, and illustrates a part of an X-Z cross-section of the semiconductor chip 10. FIG. 13 is a planar schematic diagram used to explain the third structural example of the semiconductor chip, and illustrates a part of an X-Y plane of the semiconductor chip 10. FIG. 13 is a planar schematic diagram of the semiconductor chip 10 as viewed from the side of the surface 101a.

The semiconductor chip 10 includes a substrate 101, an element layer 102, a conductive pad 103, an insulating layer 104, a bump layer 105, an insulating layer 106, an electrode 107, and a bump layer 108. Furthermore, the substrate 101, the element layer 102, the conductive pad 103, the insulating layer 104, the insulating layer 106, the electrode 107, and the bump layer 108 are the same as the substrate 101, the element layer 102, the conductive pad 103, the insulating layer 104, the insulating layer 106, the electrode 107, and the bump layer 108, respectively, in the first embodiment, and, therefore, the description thereof is omitted here.

The bump layer 105 includes a recessed portion 105a kept in contact with the conductive pad 103 in an aperture 104a and raised portions 105b provided near the aperture 104a. The other descriptions of the recessed portion 105a and the raised portions 105b can be replaced by the description of the recessed portion 105a and the raised portions 105b in the first embodiment as appropriate.

The bump layer 105 includes a first layer 151, a second layer 152, and a third layer 153. The first layer 151 is provided near the aperture 104a. A part of the side surface of the first layer 151 is exposed from the second layer 152, and the third layer 153. The second layer 152 is provided on the first layer 151 and is connected to the conductive pad 103 via the aperture 104a. The third layer 153 is provided on the second layer 152. Further description of the first layer 151, the second layer 152, and the third layer 153 can be replaced by the description of the first layer 151, the second layer 152, and the third layer 153 in the first embodiment as appropriate.

The maximum diameter D1 of the bump layer 105 is larger than the maximum diameter D2 of the electrode 107. This enables, in the case of forming a chip stacked body by stacking a plurality of semiconductor chips 10, preventing or reducing the protrusion of solder of the bump layer 108. The maximum diameter D1 of the bump layer 105 is able to be adjusted by, for example, changing the maximum diameter of the first layer 151.

As described above, according to at least one embodiment, in the case of forming a chip stacked body by stacking a plurality of semiconductor chips 10, exposing the first layer 151 of the bump layer 105 from the second layer 152 and the third layer 153 to make the maximum diameter D1 of the bump layer 105 larger than the maximum diameter D2 of the electrode 107 enables preventing or reducing the protrusion of solder of the bump layer 108.

### Fourth Embodiment

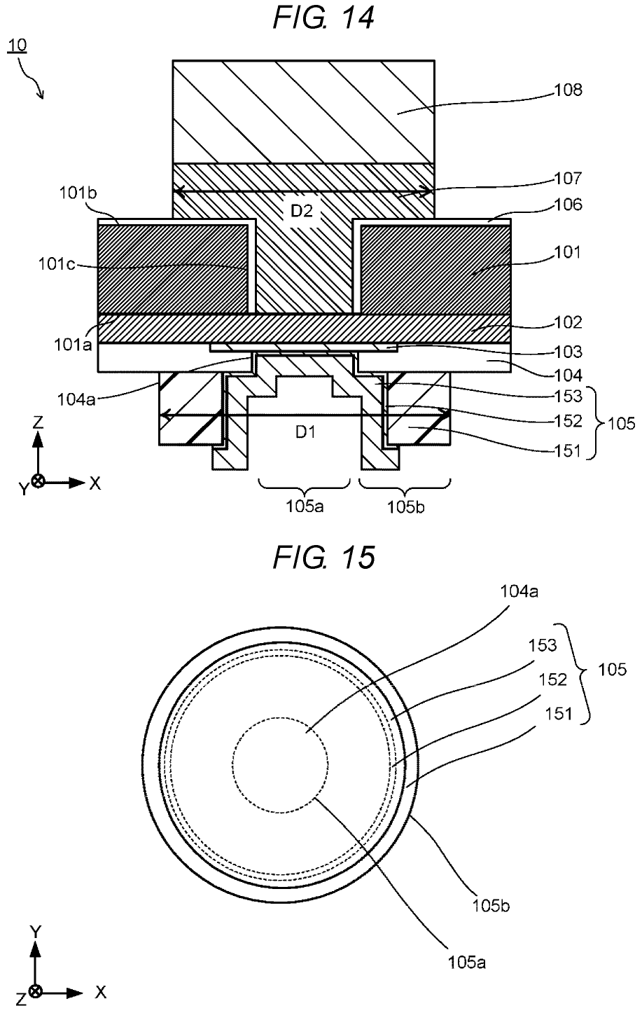

In at least one embodiment, a fourth structural example of a semiconductor chip for use in a chip stacked body is described. FIG. 14 is a sectional schematic diagram used to explain the fourth structural example of the semiconductor chip, and illustrates a part of an X-Z cross-section of the semiconductor chip 10. FIG. 15 is a planar schematic diagram used to explain the fourth structural example of the semiconductor chip, and illustrates a part of an X-Y plane of the semiconductor chip 10. FIG. 15 is a planar schematic diagram of the semiconductor chip 10 as viewed from the side of the surface 101a.

The semiconductor chip 10 includes a substrate 101, an element layer 102, a conductive pad 103, an insulating layer 104, a bump layer 105, an insulating layer 106, an electrode 107, and a bump layer 108. Furthermore, the substrate 101, the element layer 102, the conductive pad 103, the insulating layer 104, the insulating layer 106, the electrode 107, and the bump layer 108 are the same as the substrate 101, the element layer 102, the conductive pad 103, the insulating layer 104, the insulating layer 106, the electrode 107, and the bump layer 108, respectively, in the first embodiment, and, therefore, the description thereof is omitted here.

The bump layer 105 includes a recessed portion 105a kept in contact with the conductive pad 103 in an aperture 104a and an annular raised portion 105b surrounding the aperture 104a. Further description of the recessed portion 105a and the raised portion 105b can be replaced by the description of the recessed portion 105a and the raised portion 105b in the first embodiment as appropriate.

The bump layer 105 includes a first layer 151, a second layer 152, and a third layer 153. The first layer 151 surrounds the aperture 104a. A part of the side surface of the first layer 151 is exposed from the second layer 152 and the third layer 153. The second layer 152 is provided on the first layer 151 and is connected to the conductive pad 103 via the aperture 104a. The third layer 153 is provided on the second layer 152. Further description of the first layer 151, the second layer 152, and the third layer 153 can be replaced by the description of the first layer 151, the second layer 152, and the third layer 153 in the first embodiment as appropriate.

The maximum diameter D1 of the bump layer 105 is larger than the maximum diameter D2 of the electrode 107. This enables, in the case of forming a chip stacked body by stacking a plurality of semiconductor chips 10, preventing or reducing the protrusion of solder of the bump layer 108. The maximum diameter D1 of the bump layer 105 is able to be adjusted by, for example, changing the maximum diameter of the first layer 151.

As described above, according to at least one embodiment, in the case of forming a chip stacked body by stacking a plurality of semiconductor chips 10, providing the annular raised portion 105b enables preventing or reducing the collapse of the raised portion 105b. Therefore, since it is possible to prevent or reduce defective junction, the present embodiment is able to prevent or reduce a decrease in reliability of a semiconductor device.

Moreover, according to at least one embodiment, in the case of forming a chip stacked body by stacking a plurality of semiconductor chips 10, exposing the first layer 151 of the bump layer 105 from the second layer 152 and the third layer 153 to make the maximum diameter D1 of the bump layer 105 larger than the maximum diameter D2 of the electrode 107 enables preventing or reducing the protrusion of solder of the bump layer 108.

### Fifth Embodiment

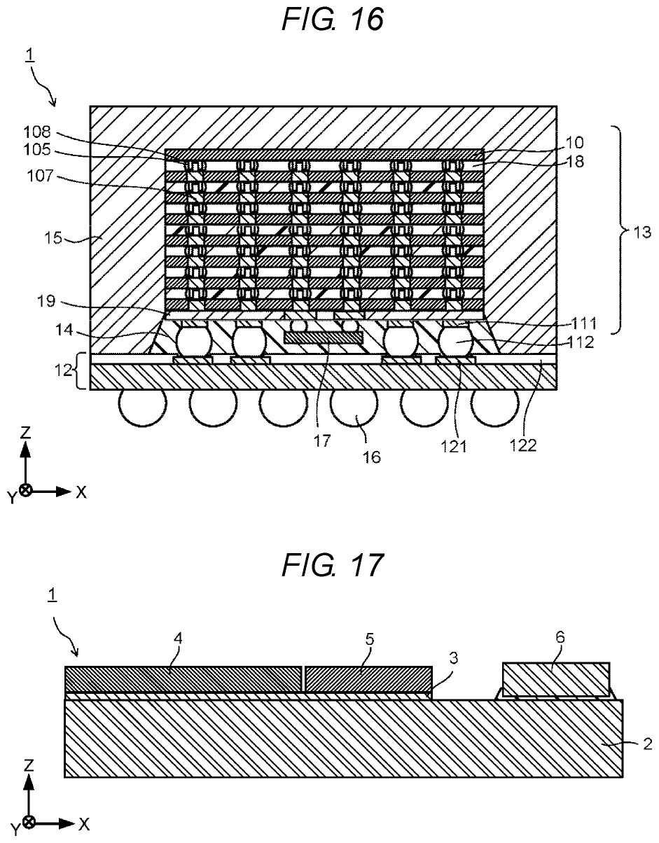

In at least one embodiment, an example of a semiconductor device configured with a chip stacked body including the semiconductor chips 10 described in the above-described embodiment is described. FIG. 16 is a sectional schematic diagram used to explain a structural example of a semiconductor device in which semiconductor chips each having a penetrating electrode such as a through-silicon via (TSV) are stacked, and illustrates a part of an X-Z cross-section of the semiconductor device 1. Furthermore, in FIG. 16, for ease of explanation, some elements are not illustrated. Furthermore, the descriptions of portions common to the elements in the other embodiments can be replaced by the descriptions of those in the other embodiments as appropriate.

The semiconductor device 1 includes a wiring substrate 12 having a first surface and a second surface located opposite each other, a chip stacked body 13 mounted on the first surface of the wiring substrate 12, a sealing resin layer 14 sealing a space between the wiring substrate 12 and the chip stacked body 13, a sealing resin layer 15 provided in such a way as to cover the chip stacked body 13, and external connection terminals 16 provided on the second surface of the wiring substrate 12.

The wiring substrate 12 includes a plurality of connection pads 121 and an insulating layer 122 exposing at least a part of the connection pads 121.

The chip stacked body 13 is electrically connected to the wiring substrate 12 via the plurality of connection pads 121 of the wiring substrate 12. The chip stacked body 13 includes a plurality of semiconductor chips 10 and a semiconductor chip 17. The semiconductor chip 10 in any one of the above-described embodiments can be applied to the plurality of semiconductor chips 10. An insulating adhesion layer 18 is provided between respective adjacent ones of the plurality of semiconductor chips 10. The insulating adhesion layer 18 seals respective spaces between the plurality of semiconductor chips 10. Furthermore, the number of stacked semiconductor chips 10 is not limited to the number of stacked semiconductor chips illustrated in FIG. 16.

The insulating adhesion layer 18 serves as a sealing material which seals a space between respective adjacent ones of the plurality of semiconductor chips 10. The insulating adhesion layer 18 may be made from, for example, a thermosetting insulating adhesive material having both an adhesion function and a sealing function, such as a non-conductive film (NCF). The insulating adhesive material includes, for example, an epoxy type resin.

The plurality of semiconductor chips 10 is electrically connected to each other via a plurality of electrodes 107 penetrating through each semiconductor chip 10 and bump layers 105 and bump layers 108 penetrating through each insulating adhesion layer 18. For example, electrically interconnecting conductive pads provided in the plurality of semiconductor chips 10 by the electrodes 107, the bump layers 105, and the bump layers 108 enables electrically connecting the plurality of semiconductor chips 10 to each other. Furthermore, when the side of the wiring substrate 12 is set as the upper surface of the chip stacked body 13, any penetrating electrode need not be provided in a semiconductor chip 10 situated on the bottom step.

The semiconductor chip 10 to be used includes, for example, a memory chip. The memory chip to be used includes, for example, a storage element such as NAND-type flash memory. Furthermore, a circuit such as a decoder may be provided in the memory chip.

When the side of the wiring substrate 12 is set as the upper surface of the chip stacked body 13, the semiconductor chip 17 is electrically connected, via a rewiring layer 19 provided on a semiconductor chip 10 situated on the top step, to the semiconductor chip 10. The rewiring layer 19 may also serve as a planarizing layer. The chip stacked body 13 is electrically connected to the wiring substrate 12 via connection pads 111 and bumps 112 provided on the rewiring layer 19.

The semiconductor chip 17 to be used may include, for example, an interface chip or a controller chip. For example, when the semiconductor chip 10 is a memory chip, a controller chip may be used as the semiconductor chip 17, read and write performed on the memory chip may be controlled by the controller chip. Furthermore, it is favorable that the semiconductor chip 17 is smaller than the semiconductor chip 10.

The chip stacked body 13 is formed by, for example, performing the following method. First, the method stacks, on one semiconductor chip 10, another semiconductor chip 10 having a bump layer 105 and an insulating adhesion layer 18 formed therein with use of, for example, a mounter, and, finally, the method bonds a semiconductor chip 10 having the rewiring layer 19 formed on the surface thereof to the stacked semiconductor chips 10. Additionally, the method performs thermal treatment to melt at least a part of the bump layer 105 or the insulating adhesion layer 18, and, after that, the method performs cooling, thus, while hardening the insulating adhesion layer 18, forming a bump layer 108 penetrating through the insulating adhesion layer 18 and electrically connecting the stacked semiconductor chips 10 to each other.

After that, the method mounts the semiconductor chip 17 on the rewiring layer 19 and forms a connection pad 111 and a plurality of bumps 112, thus forming a chip stacked body 13.

The chip stacked body 13 is, for example, reversed and mounted on the wiring substrate 12 with use of, for example, a mounter in such a manner that the rewiring layer 19 is situated inside. At this time, the order of stacking of semiconductor chips in the chip stacked body 13 becomes the reversal of that taken at the time of formation of the chip stacked body 13. Joining of the wiring substrate 12 and the chip stacked body 13 is performed using, for example, a pulse heat method. The present embodiment is not limited to this, and the chip stacked body 13 may be mounted by, after temporarily bonding the wiring substrate 12 and the chip stacked body 13, performing real adhesion using bumps 112 with reflow.

The sealing resin layer 14 may be made from, for example, an underfill resin. Furthermore, the sealing resin layer 14 does not necessarily need to be provided. For example, the sealing resin layer 14 may be formed by performing filling with an underfill resin by a dispenser using, for example, a needle.

The sealing resin layer 15 may be made from, for example, a resin material which contains an inorganic filler such as oxide silicon and which is obtained, for example, by mixing the inorganic filler with, for example, an insulating organic resin material.

The external connection terminals 16 are formed by, for example, after applying flux onto the second surface of the wiring substrate 12, mounting solder balls, melting the solder balls inside a reflow furnace, joining the solder balls to connection pads in the wiring substrate 12, and, after that, removing the flux by a solvent or pure water washing. The present embodiment is not limited to this, and the external connection terminals 16 may be formed by, for example, forming bumps. Furthermore, the number of external connection terminals 16 is not limited to the number of external connection terminals illustrated in FIG. 16.

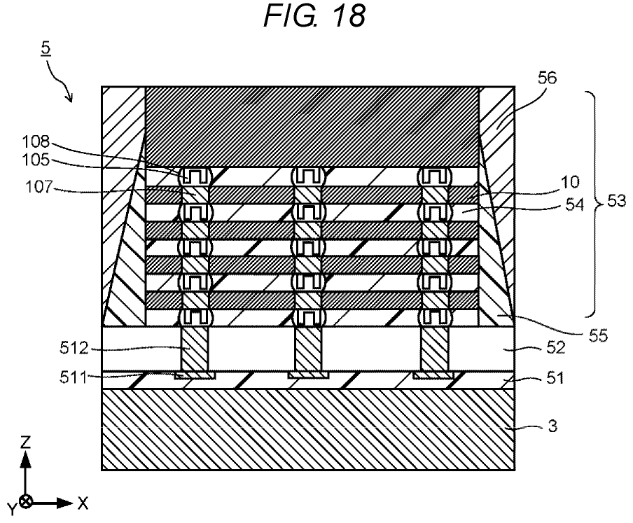

FIG. 17 is a sectional schematic diagram used to explain another structural example of a semiconductor device in which semiconductor chips each having a penetrating electrode such as a TSV are stacked, and illustrates a part of an X-Z cross-section of the semiconductor device 1. Furthermore, in FIG. 17, for ease of explanation, some elements are not illustrated. Furthermore, the description of portions common to the elements in the other embodiments can be replaced by the description of those in the other embodiments as appropriate.

The semiconductor device 1 illustrated in FIG. 17 includes a printed wiring substrate 2, an interposer substrate 3, a graphics processing unit (GPU) 4 and a memory chip 5, which are electrically interconnected via the interposer substrate 3 and solder bumps, and a reinforcement material 6 that prevents or reduces warpage of the semiconductor device 1.

FIG. 18 is a schematic diagram used to explain a structural example of the memory chip 5, and illustrates a part of an X-Z cross-section of the memory chip 5. The memory chip 5 includes an insulating layer 51 provided on the interposer substrate 3, a buffer die 52 provided on the insulating layer 51, a chip stacked body 53 provided on the buffer die 52, an insulating adhesion layer 54, a sealing resin layer 55, and a sealing resin layer 56.

The chip stacked body 53 is electrically connected to the interposer substrate 3 via the buffer die 52, electrodes 511, and electrodes 512. The chip stacked body 53 includes a plurality of semiconductor chips 10. Each semiconductor chip 10 may be any of the semiconductor chips 10 respectively described in the above-described embodiments. The insulating adhesion layer 54 is provided between respective adjacent ones of the plurality of semiconductor chips 10. The insulating adhesion layer 54 seals a space between respective adjacent ones of the plurality of semiconductor chips 10. Furthermore, the number of stacked semiconductor chips 10 is not limited to the number of stacked semiconductor chips illustrated in FIG. 18.

The plurality of semiconductor chips 10 is electrically connected to each other via a plurality of electrodes 107 penetrating through the semiconductor chip 10 and bump layers 105 and bump layer 108 penetrating through the insulating adhesion layer 54. For example, electrically connecting conductive pads provided in the plurality of semiconductor chips 10 by the electrodes 107, the bump layers 105, and the bump layer 108 enables electrically connecting the plurality of semiconductor chips 10 to each other. Furthermore, when the side of the buffer die 52 is set as the upper surface of the chip stacked body 53, any penetrating electrode does not need to be provided in a semiconductor chip 10 situated on the bottom step.

The semiconductor chip 10 to be used includes, for example, a memory chip. The memory chip to be used includes, for example, a storage element such as dynamic random access memory (DRAM). Furthermore, a circuit such as a decoder may be provided in the memory chip.

The chip stacked body 53 is formed by, for example, performing the following method. First, the method stacks, on one semiconductor chip 10, another semiconductor chip 10 having bump layers 108 and an insulating adhesion layer 54 formed therein with use of, for example, a mounter. Additionally, the method performs thermal treatment to melt at least apart of the bump layers 108 or the insulating adhesion layer 54, and, after that, the method performs cooling, thus, while hardening the insulating adhesion layer 54, forming bump layers 108 penetrating through the insulating adhesion layer 54 and electrically connecting the stacked semiconductor chips 10 to each other.

The chip stacked body 53 is, for example, reversed and mounted on the buffer die 52 with use of, for example, a mounter. At this time, the order of stacking of semiconductor chips in the chip stacked body 53 becomes the reversal of that taken at the time of formation of the chip stacked body 53. Joining of the buffer die 52 and the chip stacked body 53 is performed using, for example, a pulse heat method. At least one embodiment is not limited to this, and the chip stacked body 53 may be mounted by, after temporarily bonding the buffer die 52 and the chip stacked body 53, performing real adhesion using bumps with reflow.

The insulating adhesion layer 54 serves as a sealing material which seals a space between respective adjacent ones of the plurality of semiconductor chips 10. The insulating adhesion layer 54 may be made from, for example, a thermosetting insulating adhesive material having both an adhesion function and a sealing function, such as an NCF. The insulating adhesive material includes, for example, an epoxy type resin.

The sealing resin layer 55 may be made from, for example, an underfill resin. Furthermore, the sealing resin layer 55 does not necessarily need to be provided. For example, the sealing resin layer 55 may be formed by performing filling with an underfill resin by a dispenser using, for example, a needle.

The sealing resin layer 56 may be made from, for example, a resin material which contains an inorganic filler such as oxide silicon and which is obtained, for example, by mixing the inorganic filler with, for example, an insulating organic resin material.

As described above, according to at least one embodiment, configuring a semiconductor device using a chip stacked body in which semiconductor chips 10 described in any one of the above-described embodiments are stacked enables preventing or reducing a decrease in reliability of a semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor chip including
a conductive pad,
an insulating layer, provided on the conductive pad, and having an aperture exposing a part of the conductive pad, and
a first bump layer provided on the insulating layer and connected to the conductive pad via the aperture; and
a second semiconductor chip including an electrode and a second bump layer provided on the electrode,
wherein the first bump layer includes a recessed portion provided at the aperture and in contact with the second bump layer, and a raised portion provided adjacent the aperture and in contact with the second bump layer.

2. The semiconductor device according to claim 1, wherein the first bump layer includes:
a first layer provided adjacent the aperture; and
a second layer provided on the first layer and connected to the conductive pad via the aperture.

3. The semiconductor device according to claim 2, wherein the first layer has a higher elastic modulus than the second bump layer.

4. The semiconductor device according to claim 2, wherein the first layer contains a resin material, and
wherein the second layer contains a metallic material.

5. The semiconductor device according to claim 2, wherein the first layer contains a first metallic material, and
wherein the second layer contains a second metallic material.

6. The semiconductor device according to claim 2, wherein a maximum diameter of the first bump layer is larger than a maximum length of the electrode, and
wherein a part of a side surface of the first layer is exposed from the second layer.

7. The semiconductor device according to claim 1, wherein the raised portion surrounds the recessed portion.

8. The semiconductor device according to claim 1, wherein the first semiconductor chip includes a plurality of raised portions.

9. The semiconductor device according to claim 1, wherein the semiconductor device comprising a plurality of semiconductor chips including the first semiconductor chip and the second semiconductor chip, the plurality of semiconductor chips arranged in an array, wherein the array is a columnar array having a plurality of semiconductor columns.

10. The semiconductor device according to claim 9, further comprising a controller chip arranged to control the plurality of semiconductor chips.

11. A method for manufacturing a semiconductor device, the method comprising stacking:
a first semiconductor chip including
a conductive pad,
an insulating layer, provided on the conductive pad, having an aperture exposing a part of the conductive pad, and
a first bump layer provided on the insulating layer and connected to the conductive pad via the aperture, the first bump layer including a recessed portion provided at the aperture and a raised portion provided adjacent the aperture; and
a second semiconductor chip including an electrode and a second bump layer provided on the electrode,
wherein the recessed portion and the raised portion are in contact with the second bump layer.

12. The method according to claim 11, further comprising forming the first bump layer including forming a first layer adjacent the aperture, and forming a second layer on the conductive pad and on the first layer at the aperture.

13. The method according to claim 12, wherein the first layer has a higher elastic modulus than the second bump layer.

14. The method according to claim 12, wherein the first layer contains a resin material, and
wherein the second layer contains a metallic material.

15. The method according to claim 12, wherein the first layer contains a first metallic material, and
wherein the second layer contains a second metallic material.

16. The method according to claim 12, wherein a maximum diameter of the first bump layer is larger than a maximum diameter of the electrode, and
wherein a part of a side surface of the first layer is exposed from the second layer.

17. The method according to claim 11, wherein the raised portion surrounds the recessed portion.

18. The method according to claim 11, wherein the first semiconductor chip includes a plurality of raised portions each corresponding to the raised portion.

19. The method according to claim 12, wherein the semiconductor device comprising a plurality of semiconductor chips including the first semiconductor chip and the second semiconductor chip, wherein the plurality of semiconductor chips are arranged in an array, wherein the array is a columnar array having a plurality of semiconductor columns.

20. The method according to claim 19, further comprising a controller chip arranged to control the plurality of semiconductor chips.
